(19) United States
(12) Patent Application Publication
(10) Pub. No.: US 2018/0285607 A1
(43) Pub. Date: Oct. 4, 2018

(54) TRACKING OF ASSETS

(71) Applicant: HEWLETT PACKARD ENTERPRISE DEVELOPMENT LP, Houston, TX (US)

(72) Inventor: Ryszard Chojnacki, Bristol (GB)

(21) Appl. No.: 15/531,589

(22) PCT Filed: Dec. 2, 2014
(86) PCT No.: PCT/US2014/068009

§ 371 Date: May 30, 2017

(51) Int. Cl. G06K 7/10; H05K 7/14; G06Q 10/08; G06K 7/14; G06K 19/06

(52) U.S. Cl. CPC G06K 7/10366; H05K 7/1498; G06K 19/06037; G06Q 10/087; G06K 7/1417; H05K 7/1497

(57) ABSTRACT

An asset tracking system includes a storage medium storing asset tracking instructions and a processor to execute the instructions stored by the storage medium. The system has rack identifier instructions to read the rack identifier of a particular rack to determine a location of the rack, stack identifier instructions to read a particular stack identifier of the rack to determine a location of a particular asset associated with the stack identifier, and asset identifier instructions to read at least one asset identifier to record an identity of the asset at the determined locations. The identity of the asset includes a rack identifier, a stack identifier, and at least one asset identifier.

### BACKGROUND

Data centers often contain large fleets of computing equipment, which are often organized in racks and related infrastructures. A typical data center typically houses thousands of computers and related hardware such as networking gear. Computing equipment in a data center is typically organized in metallic racks, which are designed to maximize physical space usage. Racks may have a hierarchy structure. For example, a rack may include one or more chassis, which in turn house one or more pieces of equipment. Asset tracking and management systems may be used to manage the inventory of equipment in data centers along with data that may be collected from the physical assets.

### BRIEF DESCRIPTION OF THE DRAWINGS

The following detailed description references the drawings, wherein:

FIG. 1 is a diagram of an example system to track assets;

FIG. 2 is a diagram of an example scanner having a reader and a display showing an example graphic user interface;

FIG. 3 is a diagram of an example rack;

FIG. 4 is a diagram of an example computing device to track assets;

FIG. 5 is a flowchart of an example method for tracking assets.

### DETAILED DESCRIPTION

With the rapid growth in the use of computers to host business applications, websites, cloud, etc., the need for larger data centers to house computing hardware has also grown rapidly. A data center or server farm is a facility to house computer systems and related equipment (e.g., storage, networking switches, routers, etc.). For example, a business or organization may house all or some of its computer servers (i.e., hosts) at one or more physical locations in order to manage these systems effectively. The computer systems in a data center may be connected to clients via the Internet, Wide Area Network, Local Area Network, or other medium. Servers often host critical applications of a business, which may depend on the continuous operation and reliability of the servers. Inventory management of the computing servers can be critical in responding to critical server events that require manual intervention and in maintaining reliability of computing resources.

One current solution for data center asset management involves manual maintenance of data center inventory. However, when managing a large fleet of equipment, particular in data centers with ever increasing equipment densities, it may be difficult to maintain a full and accurate assessment of all the assets and their locations. A typical process may involve manually scanning product data into spreadsheets, where the operator is responsible for ensuring the data is complete and accurate. However, asset information varies from equipment type to type, and some assets may be a removable assembly that is part of a larger hierarchy, such as a chassis system, which may make the capture of location information difficult. The combination of large quantity, high density, variety of information, and potential hierarchy make manual collection of asset information inefficient and prone to many types of error.

As a response, solutions have been proposed that involve tracking of assets using Radio Frequency Identification (RFID). RFID systems include RFID tags that are attached to each asset for tracking. When managing large number of assets, such as 10,000s or 100,000s for large enterprise, these solutions can become expensive. Furthermore, existing RFID solutions often rely on radio frequencies that are currently unavailable in some major countries with Japan being the most notable.

Examples disclosed herein provide for systems to track assets accurately and cost effectively. In example implementations, asset tracking systems may include a plurality of assets organized in a plurality of racks, where the racks have a rack identifier and stack identifiers associated with assets housed in the rack. Example systems may have a scanner to read a rack identifier to determine the location of a particular rack, a particular stack identifier to determine a location of the particular asset associated with the stack identifier, and at least one asset identifier to create and record the identity of the particular asset at the determined locations. Furthermore, example systems may have a database manager to maintain a database of the identities of the assets and any associated data that can be scanned, such as identification information from a network prospective. In this manner, example systems provide for accurate and cost effective tracking of assets. By collecting the rack identifier, the stack identifier, and the asset identifier, example systems can provide precise tracking of each particular asset and its particular location within its rack and within the datacenter.

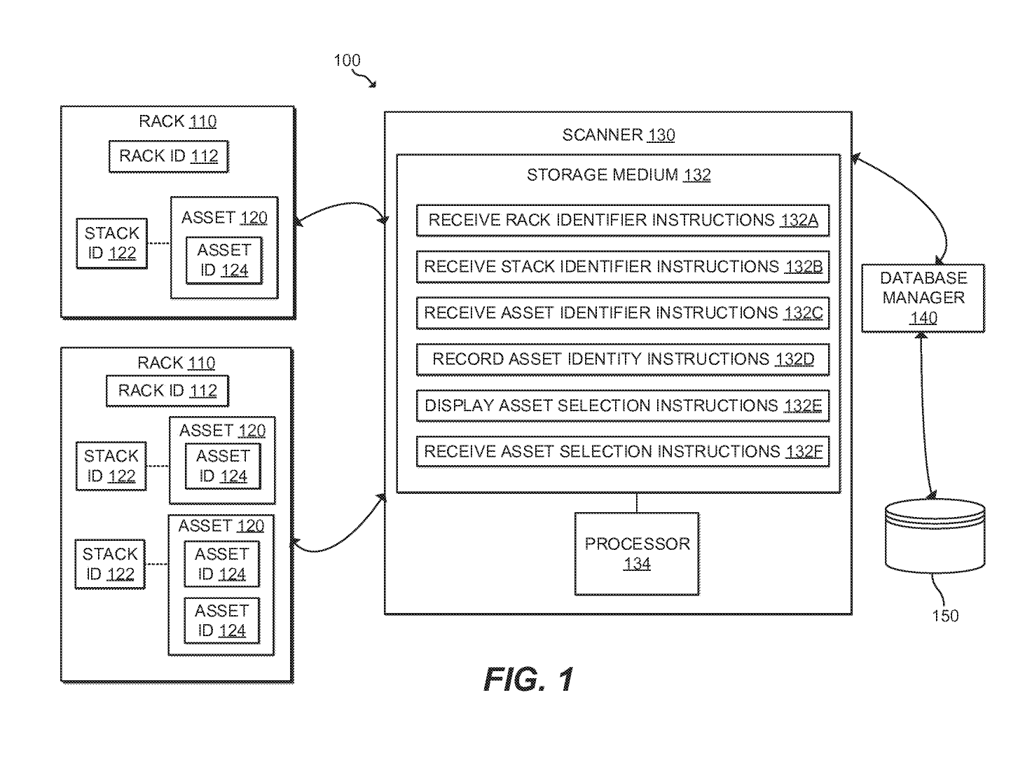

Referring now to the drawings, FIG. 1 depicts an example system 100 to track assets 120. System 100 may include a plurality of assets 120 organized in a plurality of racks 110, a scanner 130, a database manager 140, and a database 150. Each rack 110 may include a rack identifier 112, at least one asset 120, and at least one stack identifier 122, where each stack identifier 122 is associated with a different asset 120. Each asset 120 has at least one asset identifier 124. Scanner 130 is to read the rack identifier 112 of a particular rack 110 to determine a location of the particular rack 110, read a particular stack identifier 122 of the particular stack 110 to determine a location of the particular asset 120 associated with the particular stack identifier 122, and read at least one asset identifier 124 to record the identity of the particular asset 120 at the determined locations. Database manager 140 is to maintain a database 150 of the identities of the plurality of assets 120.

Rack 110 may be a container, typically a metallic cage, that houses computer systems and other related components such as storage, networking switches, and routers. Racks may be designed to maximize physical space utilization in a data center room. Each rack 110 may have a rack identifier 112. Rack identifier 112 may be a barcode or another form of machine-readable representation of data relating to the rack 110 to which it is attached. For example, rack identifier 112 may be a quick response code (QR). Rack identifier 112 may include information pertinent to identifying rack 110 to which it is attached. In some implementations, rack identifier 112 may include information regarding the owner of the rack, the datacenter or site where the rack is housed, and the location of the rack within the data center. For example, rack identifier 112 may identify a particular business unit of a company for which the server serves, the particular datacenter where it is housed, and x-axis and y-axis coordinates of the tile on which the rack 110 is located within the datacenter.

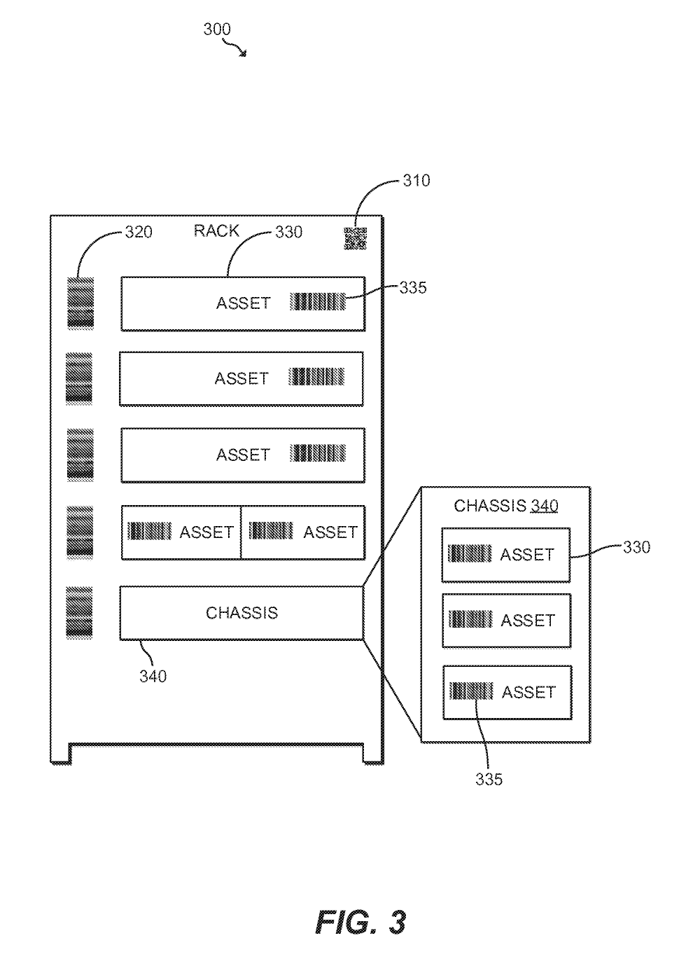

Rack 110 may house at least one asset 120 of the plurality of assets 120. Asset 120 may be computing equipment in a data center. However, asset 120 is not limited to such examples and may be other physical assets. Each rack 110 may contain at least one asset 120 sequentially stacked in the rack. For example, in a vertical rack, assets 120 may be stacked vertically, with the stacks identified by a rack unit (U), which may be a unit of measure describing the height of equipment in a rack and may be commonly defined as 1.75 inches (4.445 cm). In some implementations, rack 110 may be a full size computer rack with a height of 42 U, meaning it holds just over six feet of equipment, or a half-rack with a typical height of 18-22 U. Rack 110 may be numbered from bottom to top. For example, the bottom of the rack is 1 U, and the top is 42 U. Furthermore, in some examples, some assets 120 may be arranged in a hierarchy within rack 110. Further discussion of an asset hierarchy is found herein in relation to FIG. 3.

Rack 110 may have at least one stack identifier 122, where each stack identifier 122 is associated with a different asset 120. Stack identifier 122 may be a barcode or another form of machine-readable representation of data relating to the particular asset 120 with which it is associated. Stack identifier 122 may include information regarding the location of asset 120 inside the rack 110. For example, stack identifier 122 may have the z-axis vertical coordinates of the associated asset 120. In some implementations, stack identifier 122 may include the U number of the asset within the rack, to indicate its relative position within the vertical stack. In some implementations, stack identifiers may be mass produced, such as by a bulk printer. For example, a printer may print a long strip of stack identifiers 122 that may be placed along the vertical axis of the rack 110.

Each asset 120 may have one or more asset identifiers 124. Asset identifier 124 may be an encoded or human-readable data associated with asset 120, such as codes, numbers, letters, tags, or other information that identify the asset 120. For example, asset identifier 124 may be a serial number, product ID, or company asset tag. In some examples, an asset 120 may have a plurality of asset identifiers 124. For example, a computer server may have a product ID, a serial number, as well as a tag linking the server to a particular business unit within an enterprise. Asset identifier 124 may often be displayed on asset 120.

Scanner 130 may be a system, a device, or other mechanism that reads rack identifier 112, stack identifier 122, and asset identifier 124, and that records the identity of the associated asset 120. Scanner 130 may, for example, be a mobile computing device, with an input and an output, for a user to collect the relevant information. The input may be a scanning sensor, such as a barcode reader. The input may analyze the image data provided by the sensor to gather the contents of the scanned item. The output may then communicate the collected information to, for example, database manager 140. Scanner 130 may be a number of types, including pen-type readers, laser scanners, CCD readers, camera-based readers, video readers, barcode scanners, and other capturing devices, such as cellphones.

Scanner 130 may include a processor 134 and a non-transitory machine-readable storage medium 132 encoded with instructions to track assets. Processor 134 may be one or more central processing units (CPUs), semiconductor-based microprocessors, and/or other hardware devices suitable for retrieval and execution of instructions stored in machine-readable storage medium 132. Processor 134 may fetch, decode, and execute instructions 132A, 132B, 132C, 132D, 132E, and 132F to implement the procedures described herein. Machine-readable storage medium 132 may be any electronic, magnetic, optical, or other physical storage device that contains or stores executable instructions. Thus, storage medium 132 may be, for example, Random Access Memory (RAM), an Electrically Erasable Programmable Read-Only Memory (EEPROM), a storage device, an optical disc, and the like. Storage medium 132 may be a non-transitory storage medium, where the term “non-transitory” does not encompass transitory propagating signals. Storage medium 132 may be encoded with receive rack identifier instructions 132A, receive stack identifier instructions 132B, receive asset identifier instructions 132C, record asset identity instructions 132D, display asset selection instructions 132E, and receive asset selection instructions 132F.

Scanner 130 may read rack identifier 112 of a particular rack 110 to determine the location of rack 110, per receive rack identifier instructions 132A. Scanner 130 may scan rack identifier 112 via a sensor as described above to gather location data. For example, scanner 130 may sense the barcode or QR code of rack identifier 112 to determine the x-axis and y-axis coordinates of the rack 110 within its datacenter. In some implementations, rack identifier 112 may include additional information regarding the owner of the rack and the datacenter or site where the rack is housed.

Scanner 130 may then read a particular stack identifier 122 of the particular rack 110 to determine a location of a particular asset 120 associated with the stack identifier 122, per receive stack identifier instructions 132B. Scanner 130 may scan stack identifier 122 via a sensor as described above to gather location data. For example, scanner 130 may sense the barcode of stack identifier 122 to determine the z-axis coordinates of the associated asset 120 within the rack 110. In some examples, where an asset 120 may take up more vertical space than the space associated with a particular stack identifier, more than one stack identifier may be associated with a certain asset. Alternatively, in some implementations, only the lowest stack identifier 122 may be used to associate an asset that takes up more space than that of one stack identifier.

In some implementations, rack identifier 112 and stack identifier 122 may be permanently paired. For example, the first time that a particular rack identifier 112 and stack identifier 122 are scanned, system 100 may record that the stack identifier 122 is located on the rack identified by rack identifier 112. Pairing the two identifiers may allow effective tracking of the particular rack 110 and its assets 120 even if the rack is relocated. Furthermore, by keeping the rack and stack identifiers constant, system 100 may effectively track assets that may be added, removed, or replaced.

Scanner 130 may then read at least one asset identifier 124 of the particular asset 120 at the determined locations, per receive asset identifier instructions 132C, to record an identity of the particular asset, per record asset identity instructions 132D. Scanner 130 may scan asset identifier 124 via a sensor. As described above, asset identifier 124 may include various identifying information, such as product ID, serial number, and any associated data that can be scanned, such as identification information from a network prospective. With the sequential scanning of rack identifier 112, stack identifier 122, and asset identifier 124, scanner 120 has collected information on the owner of the asset, the datacenter where it is housed, the x-y location of the housing rack, the z-location of the asset within the rack, and characteristics of the asset. Scanner 130 may then record this identity of asset 120, where the identity may include a rack identifier 112, a stack identifier 122, and at least one asset identifier 124.

In some implementations, scanner 130 is to record the identity of an asset 120 when the asset identifier 124 of the asset 120 is correctly read at least twice consecutively. Relatedly, in some examples, scanner 130 is to reset when asset identifiers of different assets are read consecutively. This may account for user errors, such as when a user inadvertently scans the wrong asset, or errors caused by scanner 130 or other components of system 100. Furthermore, this may provide users with a way to cancel an erroneous read. To reset and start over after an unintended scan, a user may scan an asset identifier of another asset to reset scanner 130.

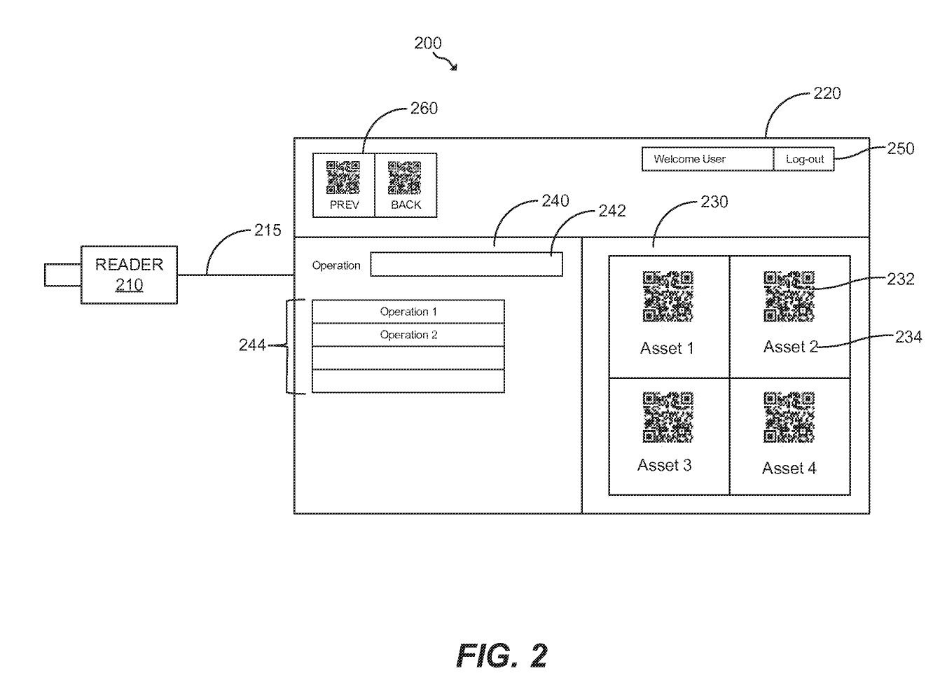

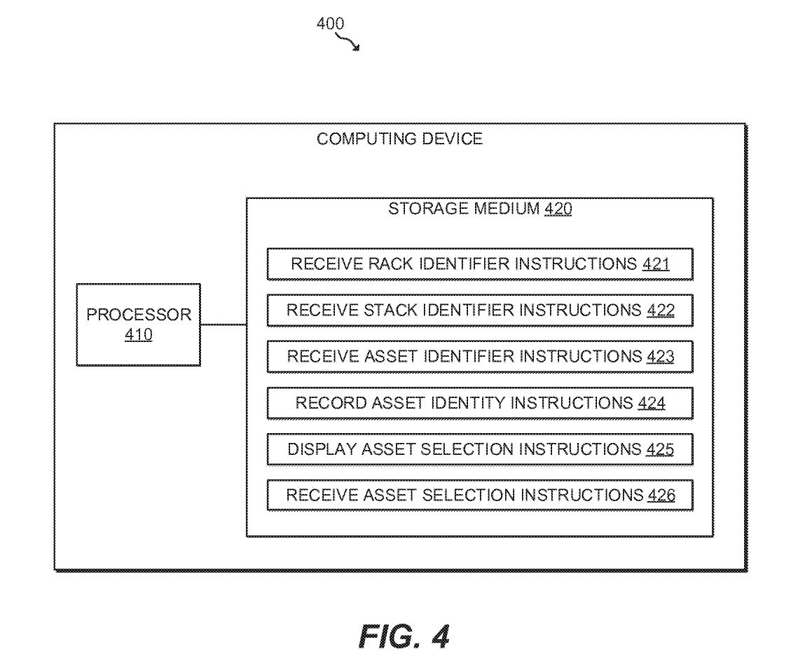

In some implementations, an asset 120 at a determined location may not have any readily accessible asset identifiers 124 to be read. In such instances, scanner 130 may display a number of asset selections via an interface, per display asset selection instructions 132E. A user may visually identify the asset and record the identity of the asset by selecting an appropriate selection from the interface. Scanner may receive the user's selection and add the selected asset identifier to the identity of the asset, per receive asset selection instructions 132F. Further details are discussed in reference to FIG. 2 and FIG. 4 herein.

After gathering the identity of the assets, scanner 130 may communicate the collected data, including the identity of asset 120, to database manager 140 by a number of methods, including wire connections such as via serial interfaces or USB connectors. Alternatively, scanner 130 may utilize wireless networks such as WLAN, Bluetooth, or radio frequencies to wirelessly communicate. Database manager 140 may maintain a database 150 of identities of assets. Database manager 140 may be one or more central processing units (CPUs), semiconductor-based microprocessors, and/or other hardware devices suitable for retrieval and execution of instructions stored in a memory device such as random access memory, machine-readable storage medium, or another form of computer data storage. Database manager 140 may be part of a computing device, which may be, for example, a notebook or desktop computer, a mobile device such as a mobile phone or tablet, a local area network (LAN) server, a web server, a cloud-hosted server, or any other suitable electronic device. In some implementations, database manager 140 may be a part of scanner 130 and not a separate device.

Database 150 may be an organization of the data collected and provided by scanner 150. Database manager 140 may run a database management system or other software application to maintain database 150. Database 150 may store the asset data in a locally connected memory storage device or remotely connected, such as over the cloud. Database manager 140 may retrieve and update information for database 150 in order to maintain a record of the assets 120.

FIG. 2 depicts an example scanner 200 having a reader 210 and a display showing an example graphic user interface (GUI) 220. As described in relation to scanner 130 of FIG. 1, scanner 200 may be a device, a system, or other mechanism that reads rack identifiers, stack identifiers, and asset identifiers, and that records the identity of assets associated with the read identifiers. Reader 210 may be an input device or system that reads optical representations of data, such as bar codes, QR codes, or other codes that make up rack identifiers, stack identifiers, and asset identifiers. Reader 210 may be, for example, a handheld barcode scanner. Reader 210 may transmit or communicate the read data to the rest of scanner 200 via data connection 215. Data connection 215 may a number of forms of communication, including via electrical wiring, optical wiring, and various forms of wireless data transmission such as Bluetooth. Furthermore, data connection 215 may transmit instructions to operate reader 210.

Scanner 200 may display various information via interface 220. In the example shown in FIG. 2, interface 220 includes a selection pane 230 and an operation pane 240. Selection pane 230 may display a number of asset selections where a user may select a particular selection to identify the particular asset associated with the particular rack identifier and stack identifier already read by reader 210. Specifically, a user may scan a rack identifier and a stack identifier to determine a particular horizontal and vertical location. In instances where the asset at that determined location does not have any readily accessible asset identifiers to be read, a user may visually identify that asset and record the identity of the asset by selecting an appropriate selection from selection pane 230. In the example shown in FIG. 2, selection pane 230 may have a number of selections 232, which are identified by a selection label 234 which tells a user what the selection 232 is. Selection 232 may be made by a user interaction, such as by selecting the selection via a touchscreen of the display. In another implementation, selections 232 are represented by QR codes that can be scanned by scanner 200.

Operation pane 240 may display an operation indicator 242 and an operation list 244. Operation indicator 242 may show the current operation being performed. For example operation indicator 242 may show an alphanumerical representation of the rack identifier, stack identifier, or asset identifier that was last scanned by reader 210. Operation list 244 may show a table or list of recent operations. For example, operation list 244 may show the most recent identifiers or assets that were scanned by reader 210.

Furthermore, interface 220 may include additional interface areas, such as user access pane 250 and navigation pane 260. In some implementations, user access pane 250 may display a welcome message and the identity of the user, such as the user's screen name or name. Additionally, user access pane 250 may include a user input detector, the triggering of which may cause the logging in or logging out of the user's account. User input may be a pressing of the touch button or other form of input. Navigation pane 260 may display at least one navigation option, which may be triggered by a user input, such as by a touch of the touchscreen or scanning of a QR code as shown in FIG. 2.

FIG. 3 depicts an example rack 300. Rack 300 may have a rack identifier 310, a plurality of assets 330 vertically stacked in the rack, and a plurality of stack identifiers 320 associated with the assets 330. Each asset 330 may have at least one asset identifier 335. Rack 300 may be a vertical server rack housing a plurality of assets 330, which may be computing resources of a datacenter. Each asset 330 may take up one or more vertical U units of rack 300.

In some implementations, an asset 330 may not take up the width of the rack. In such instances, as show in the example of FIG. 3, multiple assets 330 may be housed at one U location on the rack. These multiple assets may be arranged in a variety of configurations within the U level. In such implementations, a stack identifier 320 may be associated with more than one asset 330. To accurately track the assets, a user may scan the asset identifiers of the assets in a directional pattern. For example, because one stack identifier 320 may be associated with multiple assets, a user may scan the assets associated with that stack identifier in a consist order, such as from left to right, top to bottom, to ensure that the assets are tracked correctly.

In some implementations, rack 300 may house at least one of the assets 330 arranged in a hierarchy. For example, rack 300 may have a chassis 340 that occupies a U location on the rack. Chassis 340 may, in turn, house a plurality of the assets 330. To maintain an accurate tracking of the assets in the hierarchy, a user may read the asset identifiers 335 of the assets in a directional pattern. For example, because one stack identifier 320 may be associated with a chassis that contains multiple assets, a user may scan the assets of the chassis in a consist order, such as from left to right, top to bottom, to ensure that the assets are tracked correctly. In some implementations, a scanner, such as scanner 130, may dictate the scanning order for a particular chassis 340.

FIG. 4 depicts an example computing device 400 to track assets. Computing device 400 may be, for example, a mobile scanning device, a notebook or desktop computer, a mobile device, a local area network (LAN) server, a web server, a cloud-hosted server, any other suitable electronic device, or a combination of devices that perform the functions described herein. In the implementation shown in FIG. 4, computing device 400 includes a processor 410 and a non-transitory machine-readable storage medium 420 encoded with instructions to track assets. In some implementations, computing device 400 may be a part of a system, such as system 100 of FIG. 1.

Processor 410 may be one or more central processing units (CPUs), semiconductor-based microprocessors, and/or other hardware devices suitable for retrieval and execution of instructions stored in machine-readable storage medium 420. Processor 410 may fetch, decode, and execute instructions 421, 422, 423, 424, 425, and 426 to implement the procedures described herein. As an alternative or in addition to retrieving and executing instructions, processor 410 may include one or more electronic circuits that include electronic components for performing the functionality of one or more of instructions 421, 422, 423, 424, 425, and 426.

Machine-readable storage medium 420 may be any electronic, magnetic, optical, or other physical storage device that contains or stores executable instructions. Thus, machine-readable storage medium 420 may be, for example, Random Access Memory (RAM), an Electrically Erasable Programmable Read-Only Memory (EEPROM), a storage device, an optical disc, and the like. Storage medium 420 may be a non-transitory storage medium, where the term “non-transitory” does not encompass transitory propagating signals. As described in detail below, machine-readable storage medium 420 may be encoded with receive rack identifier instructions 421, receive stack identifier instructions 422, receive asset identifier instructions 423, record asset identity instructions 424, display asset selection instructions 425, and receive asset selection instructions 426.

Machine-readable storage medium 420 may include receive rack identifier instructions 421. In some implementations as described herein, a user may scan a rack identifier, such as a QR code, of a particular rack in a datacenter with a scanner or reader. Instructions 421 may receive the scanned data and determine pertinent information from the rack identifier. For example, instructions 421 may determine the ownership information and location of the particular rack via the received rack identifier information.

Machine-readable storage medium 420 may also include receive stack identifier instructions 422. In some implementations as described herein, a user may scan a stack identifier, such as a barcode, of a rack with a scanner or reader. Instructions 422 may receive the scanned data and determine pertinent information from the stack identifier. For example, instructions 422 may determine a vertical location of the associated asset.

Machine-readable storage medium 420 may also include receive asset identifier instructions 423. In some implementations as described herein, a user may scan an asset identifier, such as a barcode of a serial number or product ID, of an asset with a scanner or reader. Instructions 423 may receive the scanned data, and combine the data with the rack identifier and stack identifier to create an asset identity.

Machine-readable storage medium 420 may also include record asset identity instructions 424. In some implementations as described herein, instructions 424 may cause processor 410 to record the asset identity to a database and maintain the database of asset identities. The asset identity stored may, for example, include the physical location of the asset and its characteristics, as provided by the rack identifier, the stack identifier, and the asset identifiers.

In some implementations, an asset may not have an easily accessible asset identifier. For example, due to physical space constraints, it may be difficult to reach the barcode of a particular asset. In such instances and in other examples, display asset selection instructions 425 may cause processor 410 to cause to display at least one asset selection, where each asset selection represents a possible asset to associate with the particular location on the rack. A user may select an asset selection to identify the particular asset. Subsequently, receive asset selection instructions 426 may receive the asset selection and add the selected asset identifier to the identity of the particular asset. Furthermore, Database manager 140 may retrieve and update information for database 150 in order to maintain a record of the assets 120.

In some implementations, machine-readable storage medium 420 may include additional instructions, such as instructions that allow the recording of the identity of an asset when the asset identifier of the asset is correctly read at least twice consecutively. Relatedly, in some examples, additional instructions are to cause the asset reading process to reset when asset identifiers of different assets are read consecutively. This may account for user errors, such as when a user inadvertently scans the wrong asset, or errors caused by computing device 400. Furthermore, this may provide users with a way to cancel an erroneous read. To reset and start over after an unintended scan, a user may scan an asset identifier of another asset to reset the process.

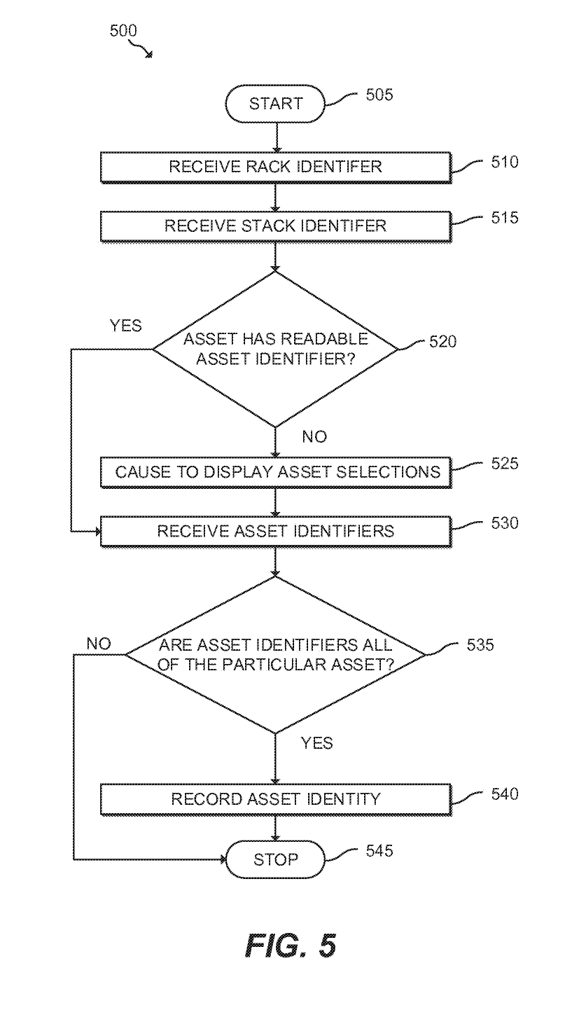

FIG. 5 depicts an example method 500 for tracking an asset. Although execution of method 500 is described below with reference to system 100 of FIG. 1, other suitable components for execution of method 500 should be apparent, including scanner 200 of FIG. 2, rack 300 of FIG. 3, and computing device 400 of FIG. 4. Method 500 may be implemented in the form of executable instructions stored on a machine-readable storage medium, such as storage medium 420, and/or in the form of electronic circuitry.

Method 500 may start in block 505 and proceed to block 510, where scanner 130 receives a rack identifier 112 from rack 110. For example, scanner 130 may receive rack identifier 112 via a sensor. For example, scanner 130 may sense the barcode or QR code of rack identifier 112 to determine the x-axis and y-axis coordinates of the rack 110 within its datacenter. In some implementations, rack identifier 112 may include additional information regarding the owner of the rack and the datacenter or site where the rack is housed.

After receiving a rack identifier, method 500 may proceed to block 515, where scanner 130 receives a stack identifier 122 from rack 110. In some implementations, scanner 130 may scan stack identifier 122 via a sensor. For example, scanner 130 may sense the barcode of stack identifier 122 to determine the z-axis coordinates of the associated asset 120 within the rack 110. In some examples, where an asset 120 may take up more vertical space than the space associated with a particular stack identifier, more than one stack identifier may be associated with a certain asset. Alternatively, in some implementations, only the lowest stack identifier 122 may be used to associate an asset that takes up more space than that of one stack identifier. In some implementations, rack identifier 112 and stack identifier 122 may be permanently paired after the first time the two are scanned. Accordingly, scanner 130 may check whether the identifiers are a correct match as previously recorded in database 150. If the identifiers are new, then database manager 140 may record the pairing for the first time.

After receiving a stack identifier, method 500 may proceed to block 520, where a user may check whether the asset 120 at the locations determined by the previous blocks has a readable asset identifier 124. For example, the asset 120 may be concealed within the rack or may not be easily accessible. If asset 130 has at least one readable asset identifier 124, then method 500 proceeds to block 530.

Alternatively, if there are no readable asset identifiers or if a user chooses not to read a readable asset identifier, method 500 proceeds to block 525 where scanner 130 causes to display a plurality of asset selections, such as on a display of scanner 130. Each asset selection may represent a possible asset to associate with the particular location on the rack. A user may select an asset selection to identify the particular asset 120.

Method 500 may subsequently proceed to block 530 where scanner 130 receives asset identifiers 124 of the asset 120. Method 500 may receive the asset identifier as a selection made by a user in block 525. Likewise, if the asset had readable assets, scanner 130 may have received, for example, asset identifier 124 via a sensor. For example, scanner 130 may sense the barcode or QR code of asset identifier 124 to determine the identity of the asset. In some implementations, scanner 130 may receive a plurality of asset identifiers 124 for a particular asset 120.

After receiving asset identifiers 124, method 500 may proceed to block 535, where scanner 130 may check whether all the asset identifiers read are all of the one particular asset. This check may prevent erroneous scans and may ensure that the user intended to scan the particular asset. If the asset identifiers are not all of the same asset, then method 500 may proceed to block 545, where method 500 may stop.

Alternatively, method 500 may proceed to block 540, where the identity of the particular asset 120 is recorded. In some implementations, the asset identity may include information obtained from the rack identifier, the stack identifier, and the asset identifiers associated with the particular asset. Scanner 130 may communicate with database manager 140 of system 100 to record the asset identity in database 150. Furthermore, a collection of the identities of the assets may be maintained in database 150. After recording the asset identities, method 500 may proceed to block 545, where method 500 may stop.

What is claimed is:

1. A system, comprising a storage medium storing asset tracking instructions and a processor to execute the instructions stored by the storage medium, wherein the instructions include:
rack identifier instructions that, when executed, cause the processor to read a rack identifier of a rack of a plurality of racks to determine a location of the rack;
stack identifier instructions that, when executed, cause the processor to read a stack identifier of the rack to determine a location of an asset associated with the stack identifier; and
asset identifier instructions that, when executed, cause the processor to read at least one asset identifier of the asset to record an identity of the asset at the determined locations, wherein the identity of the asset comprises the rack identifier, the stack identifier, and at least one of the asset identifiers.

2. The system of claim 1, further comprising:
a plurality of assets organized in a plurality of racks, wherein:
each racks comprises a rack identifier, at least one of the plurality of assets sequentially stacked in the rack, and at least one stack identifier, wherein each stack identifier is associated with a different asset; and
each asset comprises at least one asset identifier; and
a database manager to maintain a database of the identities of the plurality of assets.

3. The system of claim 2, wherein at least one of the plurality of racks comprises at least one of the plurality of assets arranged in a hierarchy.

4. The system of claim 2, wherein:
the plurality of assets comprise computing resources in a data center;
the plurality of racks comprise server racks;
the plurality of assets are vertically stacked in the racks;
and the stack identifiers identify the vertical location of their associated assets within the racks.

5. The system of claim 1, wherein the instructions further include display instructions that, when executed, cause the processor to display a plurality of asset identifiers from which a user selects at least one asset identifier to identify the asset.

6. The system of claim 1, wherein:
each rack identifier comprises a location of the rack in the x-axis and a location of the rack in the y-axis; and
each stack identifier comprises a location of the associated asset in the z-axis.

7. The system of claim 1, wherein the instructions further include:
record asset identity instructions that, when executed, cause the processor to record the identity of the particular asset at the determined location when the asset identifier of the particular asset is correctly read at least twice consecutive, and to reset the asset identity scanning process when the asset identities of different assets are consecutively.

8. The system of claim 1, wherein one of the stack identifiers is associated with at least two of the plurality of assets.

9. A non-transitory machine-readable storage medium encoded with instructions executable by a processor of a computing device, the non-transitory storage medium comprising instructions to:
receive a rack identifier of a rack, wherein the rack comprises at least one of a plurality of assets sequentially stacked in the rack, wherein each asset comprises at least one asset identifier, and wherein the rack identifier comprises a location of the rack;
receive a stack identifier of the rack, wherein the stack identifier is associated with a particular asset, and wherein the stack identifier comprises a location of the particular asset;
receive at least two asset identifiers;
record, to a database, an identity of the particular asset if the asset identifiers received are all of the particular asset, wherein the identity of the particular asset comprises the rack identifier, the stack identifier, and at least one of the asset identifiers.

10. The non-transitory storage medium of claim 9, further comprising instructions to:
cause to display a plurality of asset identifiers; and
receive a selection of an asset identifier from the displayed plurality of asset identifiers to identify the particular asset.

11. The non-transitory storage medium of claim 9, wherein:
the rack identifier comprises a location of the rack in the x-axis and a location of the rack in the y-axis; and
the stack identifier comprises a location of the particular asset in the z-axis.

12. The non-transitory storage medium of claim 9, wherein:
the plurality of assets comprise computing resources in a data center;
the rack is a server rack;
the plurality of assets are stacked vertically in the rack; and
the stack identifier identifies the vertical location of the associated asset within the rack.

13. A method of tracking an asset, comprising:
receiving a rack identifier of a rack, wherein:
the rack comprises at least one of a plurality of assets vertically stacked in the rack;
the plurality of assets comprises computing resources in a data center;
each asset comprises at least one asset identifier; and
the rack identifier comprises a location of the rack;
receiving a stack identifier of the rack, wherein the stack identifier is associated with a particular asset, and wherein the stack identifier comprises a location of the particular asset;
receiving at least two asset identifiers;
recording, to a database, an identity of the particular asset if the asset identifiers received are all of the particular asset, wherein the identity of the particular asset comprises the rack identifier, the stack identifier, and at least one of the asset identifiers.

14. The method of claim 13, further comprising:
causing to display a plurality of asset identifiers; and
receiving a selection of an asset identifier from the displayed plurality of asset identifiers to identify the particular asset

15. The method of claim 13, wherein:
the rack identifier comprises a location of the rack in the x-axis and a location of the rack in the y-axis; and
the stack identifier comprises a location of the particular asset in the z-axis.
